(19) United States
(12) Patent Application Publication
(10) Pub. No.: US 2014/0070157 A1
(43) Pub. Date: Mar. 13, 2014

(54) NONVOLATILE SEMICONDUCTOR MEMORY DEVICE

(71) Applicant: Kabushiki Kaisha Toshiba, Minato-ku (JP)

(72) Inventor: Takeshi SONEHARA, Mie-ken (JP)

(73) Assignee: Kabushiki Kaisha Toshiba, Minato-ku (JP)

(21) Appl. No.: 14/080,460

(22) Filed: Nov. 14, 2013

Related U.S. Application Data
(62) Division of application No. 13/040,756, filed on Mar. 4, 2011.

(30) Foreign Application Priority Data
Apr. 21, 2010 (JP) 2010-097775

(51) Int. Cl. H01L 45/00

(52) U.S. Cl. CPC H01L 45/12
USPC 257/2

(57) ABSTRACT

According to one embodiment, a nonvolatile semiconductor memory device includes a memory portion and a rectifying element. The memory portion includes a cathode electrode, a memory layer, and an anode electrode. The rectifying element is connected to one of the cathode electrode and the anode electrode, or incorporates the memory portion into an inner portion of the rectifying element. The rectifying element includes a first semiconductor layer, a second semiconductor layer, and an insulating layer provided between the first semiconductor layer and the second semiconductor layer, and the first semiconductor layer and the second semiconductor layer are a p⁺ semiconductor layer or an n⁺ semiconductor layer.

### CROSS-REFERENCE TO RELATED APPLICATIONS

This application is a division of and claims the benefit of priority under 35 U.S.C. §120 from U.S. Ser. No. 13/040,756 filed Mar. 4, 2011, and claims the benefit of priority under 35 U.S.C. §119 from Japanese Patent Application No. 2010-097775 filed Apr. 21, 2010; the entire contents of each of which are incorporated herein by reference.

### FIELD

Embodiments described herein relate generally to a nonvolatile semiconductor memory device.

### BACKGROUND

In recent years, a nonvolatile semiconductor memory device that includes an electrically re-programmable variable resistance element (RRAM (Registered Trademark) or ReRAM (resistance random access memory)), or a phase change element (phase change random access memory (PRAM)) is attracting attention as the successor to flash memories (for example, refer to JP-A 2009-217908 (Kokai)).

When multiple variable resistance elements, phase change elements, or the like are stacked to configure a nonvolatile semiconductor memory device, operation of only selected memory cells requires that application of current to non-selected cells must be prevented. Consequently, a rectifying element such as an Si diode (pn diode or pin diode), or the like must be provided.

When a nonvolatile semiconductor memory device is configured by three-dimensional stacking of multiple variable resistance elements, phase change elements, or the like, a fixed-value current may result. Therefore when a thin rectifying element is not used, there is a risk that an increase in the aspect ratio will have an adverse effect on processing.

Therefore, there is a need to reduce the thickness of a rectifying element while maintaining rectifying performance.

### BRIEF DESCRIPTION OF THE DRAWINGS

FIG. 1 is a schematic perspective view illustrating a nonvolatile semiconductor memory device according the embodiment;

FIG. 2 is a schematic sectional view illustrating the nonvolatile semiconductor memory device according the embodiment;

FIG. 3 is a schematic perspective view illustrating the case of unipolar operation;

FIG. 4 is a schematic perspective view illustrating the case of bipolar operation;

FIGS. 5A and 5B show schematic views of an energy band of the rectifying element according to the embodiment;

FIG. 6 is a schematic graph illustrating the current-voltage characteristics of the rectifying element according to the embodiment;

FIG. 7A is a schematic view illustrating the configuration of the rectifying element according to a first variation, and FIG. 7B is a schematic view illustrating the energy band during application of bias to the rectifying element according to the first variation;

FIG. 8 is a schematic graph illustrating the current-voltage characteristics of the rectifying element according to the first variation;

FIG. 9A is a schematic view illustrating the insulating layer formed from multiple layers having a different electron barrier height and FIGS. 9B and 9C are schematic views illustrating electron passage;

FIG. 10A is a schematic graph illustrating current-voltage characteristics when the insulating layer is a single layer, and FIG. 10B is a schematic graph illustrating current-voltage characteristics when the insulating layer is formed from multiple layers;

FIG. 11 is a schematic perspective view illustrating the configuration of a rectifying element according to a third variation;

FIG. 12A illustrates operation during application of a weak voltage, and FIG. 12B illustrates the operation when a higher voltage is applied;

FIG. 13A illustrates operation during application of a weak voltage, and FIG. 13B illustrates operation when a higher voltage is applied;

FIG. 14 is a schematic perspective view illustrating the configuration of a rectifying element according to a fourth variation;

FIG. 15A illustrates operation during application of a weak voltage, and FIG. 15B illustrates operation when a higher voltage is applied;

FIG. 16A illustrates operation during application of a weak voltage, and FIG. 16B illustrates operation when a higher voltage is applied; and

FIG. 17 is a schematic graph illustrating the current-voltage characteristics of the rectifying element according to the fourth variation.

### DETAILED DESCRIPTION

In general, according to one embodiment, a nonvolatile semiconductor memory device includes a memory portion and a rectifying element. The memory portion includes a cathode electrode, a memory layer, and an anode electrode. The rectifying element is connected to one of the cathode electrode and the anode electrode, or incorporates the memory portion into an inner portion of the rectifying element. The rectifying element includes a first semiconductor layer, a second semiconductor layer, and an insulating layer provided between the first semiconductor layer and the second semiconductor layer, and the first semiconductor layer and the second semiconductor layer are a p⁺ semiconductor layer or an n⁺ semiconductor layer.

In general, according to one embodiment, a nonvolatile semiconductor memory device includes a memory portion and a rectifying element. The memory portion includes a cathode electrode, a memory layer, and a anode electrode. The rectifying element is connected to one of the cathode electrode and the anode electrode, or incorporates the memory portion into an inner portion of the rectifying element. The rectifying element includes a metal layer, a third semiconductor layer, and an insulating layer provided between the metal layer and the third semiconductor layer, and the third semiconductor layer is a p⁺ semiconductor layer or an n⁺ semiconductor layer.

A characteristic feature of the nonvolatile semiconductor memory device according to an embodiment of the invention is a configuration of a rectifying element that is provided in the nonvolatile semiconductor memory device.

Firstly, the configuration will be described.

For example, the variable resistance element provided in the nonvolatile semiconductor memory device is configured from a memory layer/electrode formed from a variable resistance material such as an electrode/binary or tertiary metal oxide, or the like. This type of variable resistance element includes a bipolar type that switches between a high-resistance state and a low-resistance state by varying the polarity of the applied voltage, and a unipolar type that switches between a high-resistance state and a low-resistance state by controlling the voltage and the application period without varying the polarity of the applied voltage.

The unipolar type is preferred when the above configurations are used to realize a high-density memory cell array. When using the unipolar type, the cell array can be configured by stacking a rectifying element such as a diode and a variable resistance element at each cross point of a bit line and a word line. As a result, a three-dimensional stacked memory can be realized that increases the memory capacity without increasing the surface area of the cell array portion.

Although the bipolar type is associated with a risk of an increase in the chip surface area, enhanced operational speeds and enhanced retention are enabled as a result of the variable resistance material.

In the case of unipolar operation, a rectifying element such as a diode must be provided to allow current flow only along one voltage direction. In the case of bipolar operation, a rectifying element must be provided so that current does not flow below a reference voltage Vth resulting in bidirectional current flow.

An example of a unipolar type includes different values depending on the variable resistance material when programming (SET) into a single memory cell. However a current having a current density of 1e6 through 1e10, or a voltage of 1 through 2 V must be applied to the variable resistance element (not including the rectifying element). For this reason, a current must be applied to the rectifying element so that a specific voltage or specific current is applied to the variable resistance element.

Furthermore when erasing (RESET) a selected memory cell, a current having a current density of 1e6 through 1e10, or a voltage of 1 through 3 V must be applied to the variable resistance element (not including the rectifying element). Consequently, the current value and the voltage value required during programming (SET) or erasing (RESET) take specific values that are respectively determined by the variable resistance material. For this reason, a current must be applied to the rectifying element so that a specific current or a specific voltage is applied to the variable resistance element.

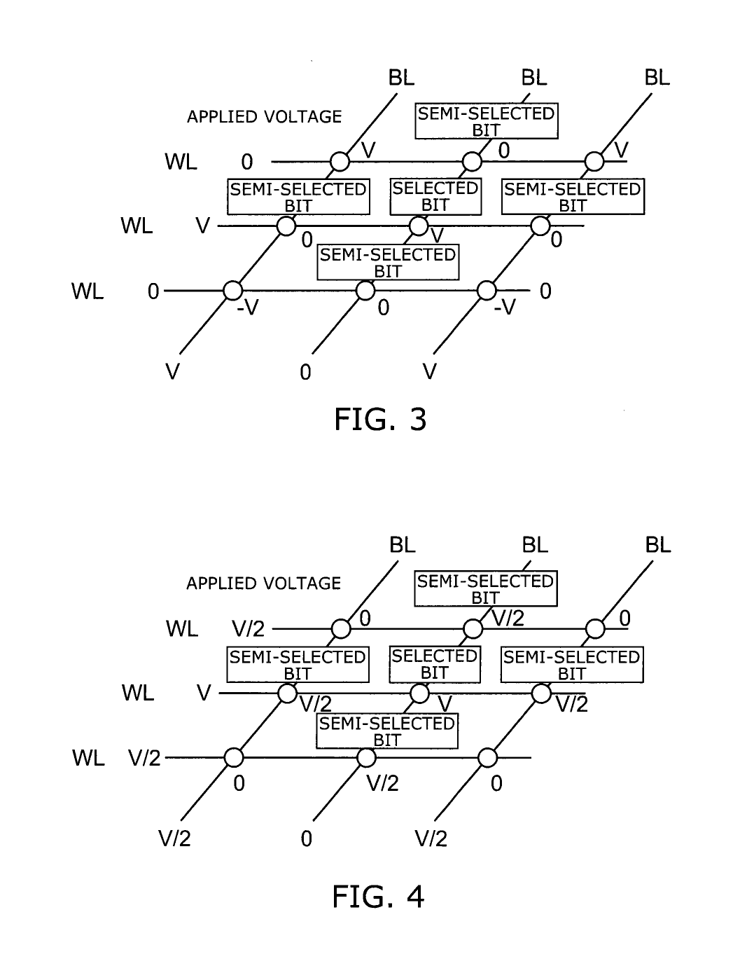

However, since multiple memory cells are connected to a single bit line BL or word line WL, a voltage is also applied to a memory cell other than the selected memory cells to thereby execute an erase (RESET) operation. As illustrated in FIG. 3, since a reverse bias is applied to a memory cell other than the selected memory cell (selected Bit), a rectifying element must suppress a reverse current (a current in an opposite direction), or an OFF current.

On the other hand, as shown in FIG. 4, bipolar operation basically differs from unipolar operation in relation to the following points.

(1) Application of bi-directional current;

(2) Different operational speed and operational current (voltage) from unipolar operation as a result of the variable resistance material.

(3) A non-selected bit is in a semi-selected state in which a V/2 voltage is applied. Since the current at this time is a reverse current in relation to the diode, a rectifying element must be used that does not allow current flow of V/2 or less. Therefore, the trade-off between reducing the aspect ratio and suppressing the reverse current or OFF current creates problems during both unipolar operation and bipolar operation.

Furthermore, there is a possibility of the following problems in addition to the above points when actually performing programming (SET) operations or erasing (RESET) operations in relation to an actual memory cell array. Consequently, the following conditions must be satisfied during application of a large capacity nonvolatile semiconductor memory device that employs a variable resistance element (RRAM) (Registered Trademark) or a ReRAM, or a phase change element (PRAM), in addition to a rectifying element.

(1) Reduction of the thickness of the memory cell, or facilitating miniaturization while suppressing variability in memory cell characteristics;

(2) Configuration of an energy-efficient nonvolatile semiconductor memory device (enabling reduction of OFF current);

(3) Increasing forward current (or ON current), suppression of reverse current (or OFF current), and superior resistance to damage caused by application of high voltage.

Particularly important features of the above include reducing the thickness which is required for fine processing (reduction of the total thickness when the thickness of the rectifying element is added to the memory element thickness), and suppressing reverse current or OFF current.

This is due to the risk of an adverse effect on processing operations being caused by an increase in the aspect ratio in the event that the thickness is not reduced. Furthermore, when the reverse current or the OFF current is not suppressed, there is a risk of erroneous operation of a memory cell other than the selected memory cell (selected Bit), a risk of failure of reading (READ) operations, and a risk of failure of energy efficient operation.

Although a conventional configuration uses an Si-pn diode as a rectifying element, use of the Si-pn diode is associated with fundamental problems related to principle of operation, structure and thermal deterioration during formation, and therefore thickness reduction and suppression of the reverse current or the OFF current becomes problematic.

Consequently, a solution of these problems requires a rectifying element that enables non-ohmic current characteristics by use of a material that enables thickness reduction and low-temperature formation.

In the embodiment, an insulating layer is provided in the rectifying element, and the insulating layer is sandwiched by semiconductor layers. For example, the rectifying element may be configured by a p⁺ semiconductor layer-insulating layer-p⁺ semiconductor layer, an n⁺ semiconductor layer-insulating layer-n⁺ semiconductor layer, or a p⁺ semiconductor layer-insulating layer-n⁺ semiconductor layer.

Furthermore, the insulating layer may be sandwiched by a semiconductor layer and a metal layer. For example, a configuration such as a p⁺ semiconductor layer-insulating layer-metal layer, or an n⁺ semiconductor layer-insulating layer-metal layer may be provided.

In addition, an intrinsic semiconductor layer may be provided between the semiconductor layer and the insulating layer.

The term intrinsic semiconductor layer here also includes an n⁻ semiconductor layer and a p⁻ semiconductor layer doped with 10¹⁸/cm³ or less.

The insulating layer may be a single layer, or may be formed from multiple layers having a different electron barrier height and/or a different dielectric constant.

The embodiment employs a p⁺ semiconductor layer and an n⁺ semiconductor layer. In other words, the p⁺ semiconductor layer and the n⁺ semiconductor layer have a higher impurity concentration than a p semiconductor layer or an n semiconductor layer.

In this context, an increase in the impurity concentration is associated with the following advantages.

(1) In light of bonding characteristics with a metal such as an electrode, the interface resistance caused by a Schottky junction can be reduced.

(2) Undesirable variation in rectification characteristics can be reduced when miniaturizing a memory cell. For example, when the impurity concentration is 10¹⁵/cm³, there is only one impurity atom per 100 nm³. However, when the impurity concentration is 10¹⁹/cm³, the rectification characteristics are determined by the presence or absence of 10000 impurity atoms per 100 nm³. In other words, when the impurity concentration is 10¹⁵/cm³, the rectification characteristics are determined by the presence or absence of one impurity atom per 100 nm³. On the other hand, when the impurity concentration is 10¹⁹/cm³, even when there is not one impurity atom per 100 nm³, 9999 impurity atoms still remain. Consequently, variation in the rectification characteristics can be made extremely small.

However, the following disadvantages are caused by excessive increase of the impurity concentration.

When the impurity concentration is excessively increased, the number of impurity-based carriers becomes excessively high, and there is a risk that the OFF current will increase. As a result, the impurity concentration is preferably reduced in order to suppress the OFF current.

In light of the above points, the embodiment uses an impurity concentration not less than 10¹⁸/cm³, and not more than 10²²/cm³, and for example, the impurity concentration may be 10²¹/cm³.

Furthermore, when a semiconductor layer having the same conductivity type such as a p⁺ semiconductor layer-insulating layer-p+ semiconductor layer, an n⁺ semiconductor layer-insulating layer-n+ semiconductor layer, or the like sandwiches the insulating layer, the rectification characteristics can be asymmetrically configured by creating a relative concentration difference in the semiconductor layers sandwiching the insulating layer.

Furthermore, when a semiconductor layer having a different conductivity type such as a p⁺ semiconductor layer-insulating layer-n⁺ semiconductor layer, or the like sandwiches the insulating layer, OFF-current suppression is facilitated by increasing the impurity concentration in both the p⁺ semiconductor layer and the n⁺ semiconductor layer. Furthermore parasitic resistance can be reduced.

Therefore in light of the above points, the impurity concentration is not less than 10²⁰/cm³ and not more than 10²²/cm³.

Various embodiments will be described hereinafter with reference to the accompanying drawings. In each of the drawings, those constituent elements that are the same are denoted by the same reference numerals, and detailed description will be omitted as appropriate.

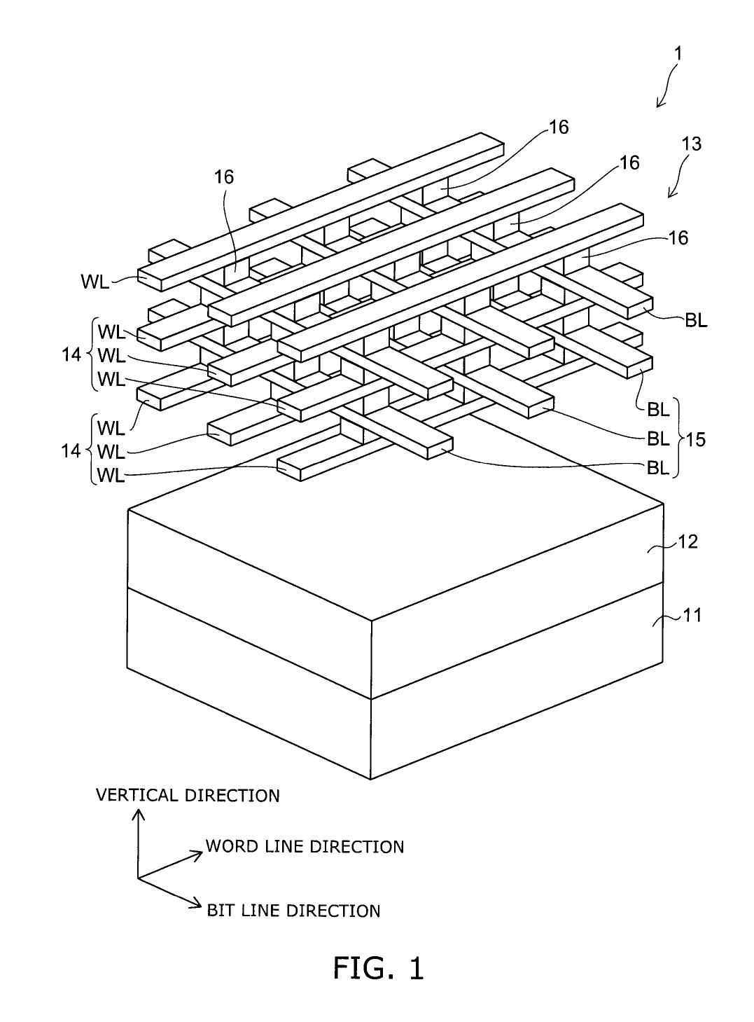

FIG. 1 is a schematic perspective view illustrating a nonvolatile semiconductor memory device according the embodiment.

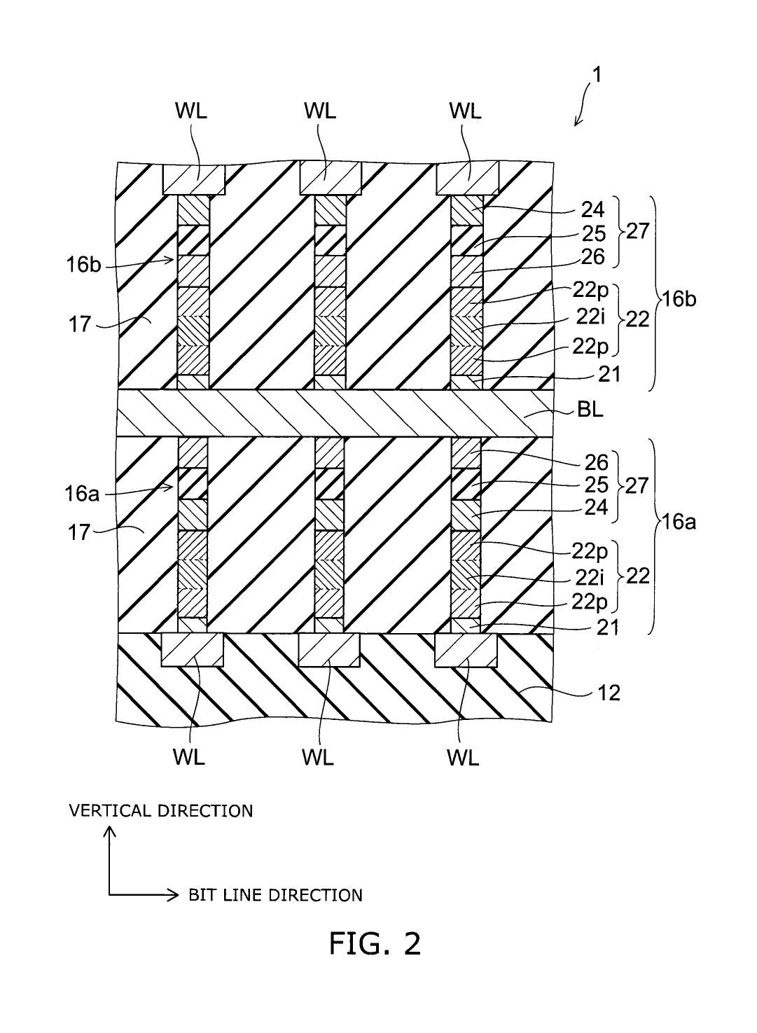

FIG. 2 is a schematic sectional view illustrating the nonvolatile semiconductor memory device according the embodiment.

The nonvolatile semiconductor memory device according the embodiment is exemplified by a resistance random access memory (ReRAM).

As illustrated by FIG. 1, a nonvolatile semiconductor memory device 1 includes a silicon substrate 11. Drive circuits (not shown) for the nonvolatile semiconductor memory device 1 are formed on an upper surface and an upper layer portion of the silicon substrate 11. An interlayer insulating film 12 formed from silicon oxide is provided on the silicon substrate 11 to embed a drive circuit, and a memory cell portion 13 is provided on the interlayer insulating film 12.

In the memory cell portion 13, a word line interconnect layer 14 that has multiple word lines WL extending in a parallel direction on an upper surface of the silicon substrate 11 (hereinafter referred to as “word line direction”) and a bit line interconnect layer 15 that has multiple bit lines BL extending in a parallel direction on an upper surface of the silicon substrate 11, intersecting with the word line direction, for example in an orthogonal direction (hereinafter referred to as “bit line direction”) are alternately stacked via an insulating layer. In this configuration, the word lines WL, the bit lines BL, and the word lines WL and bit lines BL do not come into mutual contact.

A pillar 16 is provided at the most proximate connection point between each word line WL and each bit line BL to thereby extend in a direction perpendicular to the upper surface of the silicon substrate 11 (hereinafter referred to as “vertical direction”). A single pillar 16 constitutes a single memory cell. In other words, the nonvolatile semiconductor memory device 1 is a so-called cross-point nonvolatile semiconductor memory device in which a memory cell is disposed at each most proximate connection point between a word line WL and a bit line BL. The word line WL, the bit line BL and the pillar 16 are embedded by an interlayer insulating layer 17 (refer to FIG. 2) that is formed by a silicon oxide for example.

An example of the configuration of the pillar 16 will be described below.

As shown in FIG. 2, the pillar 16 includes two types being a pillar 16a that has a word line WL disposed on the lower side and a bit line BL disposed on the upper side, and a pillar 16b that has a bit line BL disposed on the lower side and a word line WL disposed on the upper side.

The pillar 16a includes a lower electrode 21, a rectifying element 22 and a memory portion 27 that are stacked in order from the lower side (word-line side) to the upper side (bit-line side).

The memory portion 27 includes a cathode electrode 24, a memory layer 25, and an anode electrode 26.

The lower electrode 21 is connected to the word line WL, and the anode electrode 26 is connected to the bit line BL. When the rectifying element has a metal layer 22m described below, the lower electrode 21 may also function as the metal layer 22m of the rectifying element.

The cathode electrode 24 and the anode electrode 26 may include a function as a barrier metal layer or an adhesion layer. When the rectifying element has a metal layer 22m described below, the cathode electrode 24 or the anode electrode 26 provided on the rectifying element side may also function as the metal layer 22m of the rectifying element.

A memory element is configured by the cathode electrode 24 and the anode electrode 26 sandwiching the memory layer 25. A potential that is supplied to the bit line BL is higher than that supplied to the word line WL. The cathode electrode 24 is connected to the word line WL through the rectifying element 22 or the like, and the anode electrode 26 is connected to the bit line BL. As a result, a potential that is relatively negative is applied to the cathode electrode 24, and a potential that is relatively positive is applied to the anode electrode 26.

In contrast to the pillar 16a, the memory element in the pillar 16b is stacked in order in an opposite direction relative to the word line WL. However, the configuration of the rectifying element 22 below the memory element, that is to say, the disposition on the silicon substrate 11 side remains unchanged. That is to say, the pillar 16b includes the lower electrode 21, the rectifying element 22, the anode electrode 26, the memory layer 25, and the cathode electrode 24 that are aligned in order from the lower side (word-line side) to the upper side (bit-line side). In this configuration, the lower electrode 21 is connected to the bit line BL, and the cathode electrode 24 is connected to the word line WL.

The memory layer 25 may be, for example, a variable resistance layer, or a phase change layer.

A variable resistance layer is a layer that is formed from a material in which a resistance value varies as a result of voltage, current, heat, or the like. A phase change layer is a layer formed from a material in which physical characteristics such as capacitance or the resistance value change in response to a phase change.

In this configuration, the phase change includes the following.

For example, the phase change includes a metal-semiconductor transition, a metal-insulator transition, a metal-metal transition, an insulator-insulator transition, an insulator-semiconductor transition, an insulator-metal transition, a semiconductor-semiconductor transition, a semiconductor-metal transition, and a semiconductor-insulator transition.

Furthermore, this may include a quantum-state phase change (for example, a metal-superconductor transition, or the like).

It may also include a paramagnetic-ferromagnetic transition, an antiferromagnetic-ferromagnetic transition, a ferromagnetic-ferromagnetic transition, a ferrimagnetic-ferromagnetic transition, or a combination thereof.

It may also include a paraelectric-ferroelectric transition, a paraelectric-pyroelectric transition, a paraelectric-piezoelectric transition, a ferroelectric-ferroelectric transition, an antiferroelectric-ferroelectric transition, or a combination thereof.

Alternatively, a transition may include a combination of the above transitions.

For example, the transition may be a transition from a metal, insulator, semiconductor, ferroelectric material, paraelectric material, pyroelectric material, piezoelectric material, ferromagnetic material, ferrimagnetic material, helimagnetic material, a paramagnetic material, or an antiferromagnetic material, to a ferroelectric/ferromagnetic material, or a transition in the inverse direction.

The variable resistance layer is thereby defined to include the phase change layer.

A memory layer 25 may, for example, be formed from a metal oxide, a metal compound, an organic thin film, carbon, carbon nanotubes, or the like. The material forming the memory layer 25 will be described in detail below.

A low resistance variable memory such as a resistance random access memory (ReRAM) in which the memory layer 25 is a variable resistance layer, a phase change random access memory (PCRAM) in which the memory layer 25 is a phase change layer, or the like includes a memory cell array in a cross-point configuration, realizes a large memory capacity by three-dimensional stacking, and enables high-speed operation similar to a dynamic random access memory (DRAM).

Further examples of the material used in the memory layer 25 will be described below.

The memory layer 25 may be formed for example from an oxide, an oxynitride, or the like.

The oxide for example, includes silicon oxide (SiO₂), aluminum oxide (Al₂O₃), yttrium oxide (Y₂O₃), lanthanum oxide (La₂O₃), gadolinium oxide (Gd₂O₃), cerium (III) oxide (Ce₂O₃), cerium oxide (CeO₂), tantalum oxide (Ta₂O₅), hafnium oxide (HfO₂), zirconium oxide (ZrO₂), titanium oxide (TiO₂), hafnium silicate (HfSiO), hafnium aluminate (HfAlO), zirconium silicate (ZrSiO), zirconium aluminate (ZrAlO), aluminum silicate (AlSiO), or the like.

An oxide may also be represented as “AB₂O₄”.

In this case, “A” and “B” may be the same element or different elements, and for example include aluminum (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), and the like.

For example, the oxide may include iron (III) oxide (Fe₃O₄), hercynite (FeAl₂O₄), Mn₁₊ₓAl₂₋ₓO_{4+y}, Co₁₊ₓAl₂₋ₓO_{4+y}, MnOₓ, or the like.

An oxide may also be represented as “ABO₃”.

As used herein, “A” and “B” may be the same element or different elements, and for example include aluminum (Al), lanthanum (La), hafnium (Hf), tantalum (Ta), tungsten (W), rhenium (Re), osmium (Os), iridium (Ir), platinum (Pt), gold (Au), mercury (Hg), thallium (TI), lead (Pb), bismuth (Bi), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), yttrium (Y), zirconium (Zr), niobium (Nb), molybdenum (Mo), technetium (Tc), ruthenium (Ru), rhodium (Rh), lead (Pb), silver (Ag), cadmium (Cd), indium (In), tin (Sn), and the like.

For example, the oxide may include lanthanum aluminate (LaAlO₃), strontium hafnate (SrHfO₃), strontium zirconate (SrZrO₃), strontium titanate (SrTiO₃), or the like.

The oxynitride for example, includes silicon oxynitride (SiON), aluminum oxynitride (AlON), yttrium oxynitride (YON), lanthanum oxynitride (LaON), gadolinium oxynitride (GdON), cerium oxynitride (CeON), tantalum oxynitride (TaON), hafnium oxynitride (HfON), zirconium oxynitride (ZrON), titanium oxynitride (TiON), LaAlON, SrHfON, SrZrON, SrTiON, hafnium silicate (HfSiON), HfAlON, ZrSiON, ZrAlON, AlSiON, or the like.

The memory layer 25 may be formed from a binary or tertiary metal oxide or organic compound (including a single layer film or nanotube). For example, when carbon is used, the layer may be a single layer film, or may be a three-dimensional structure such as a nanotube, graphene, fullerene, or the like. The metal oxide may be an oxide or an oxynitride as described above.

The memory layer 25 may be formed from a multiple layers. For example, the memory layer 25 including the multiple layers may be realized by combination of the materials described above. Furthermore, layers made of the above materials, the p-type semiconductor, the n-type semiconductor and the intrinsic semiconductor may be combined appropriately. Metal elements illustrated below may be introduced into stacked interface of the multiple layers.

The word line WL and the bit line BL may be formed from tungsten (W), tungsten nitride (WN), aluminum (Al), titanium (Ti), vanadium (V), chromium (Cr), manganese (Mn), iron (Fe), cobalt (Co), nickel (Ni), copper (Cu), titanium nitride (TiN), tungsten silicide (WSiₓ), tantalum silicide (TaSiₓ), palladium silicide (PdSiₓ), erbium silicide (ErSiₓ), yttrium silicide (YSiₓ), platinum silicide (PtSiₓ), hafnium silicide (HfSiₓ), nickel silicide (NiSiₓ), cobalt silicide (CoSiₓ), titanium silicide (TiSiₓ), vanadium silicide (VSiₓ), chromium silicide (CrSiₓ), manganese silicide (MnSiₓ), iron silicide (FeSiₓ), or the like.

The cathode electrode 24, the anode electrode 26, and the lower electrode 21 may be formed from a single metal element, a mixture of multiple metal elements, a silicide or an oxide, or a nitride, or the like.

For example, it may be formed from platinum (Pt), gold (Au), silver (Ag), titanium aluminum nitride (TiAlN), strontium ruthenium oxide (SrRuO), ruthenium (Ru), ruthenium nitride (RuN), iridium (Ir), titanium (Ti), vanadium (V), chromium (Cr), manganese (Mn), iron (Fe), cobalt (Co), nickel (Ni), copper (Cu), titanium nitride (TiN), tantalum nitride (TaN), lanthanum nickelate (LaNiO), aluminum (Al), PtIrOₓ, PtRhOₓ, rhodium (Rh), TaAlN, SiTiOₓ, tungsten silicide (WSiₓ), tantalum silicide (TaSiₓ), palladium silicide (PdSiₓ), platinum silicide (PtSiₓ), iridium silicide (IrSiₓ), erbium silicide (ErSiₓ), yttrium silicide (YSiₓ), hafnium silicide (HfSiₓ), nickel silicide (NiSiₓ), cobalt silicide (CoSiₓ), titanium silicide (TiSiₓ), vanadium silicide (VSiₓ), chromium silicide (CrSiₓ), manganese silicide (MnSiₓ), iron silicide (FeSiₓ), or the like.

The rectifying element 22 is connected to the cathode electrode 24 or the anode electrode 26.

The rectifying element 22 shown in FIG. 2 is configured by stacking a p⁺ semiconductor layer 22p (first semiconductor layer), an insulating layer 22i, and a p⁺ semiconductor layer 22p (second semiconductor layer). However there is no limitation in this respect, and an n⁺ semiconductor layer 22n, an insulating layer 22i, and an n⁺ semiconductor layer 22n may be stacked. In addition, a configuration that stacks a p⁺ semiconductor layer 22p, an insulating layer 22i, and an n⁺ semiconductor layer 22n, or a configuration that stacks an n⁺ semiconductor layer 22n, an insulating layer 22i, and an p⁺ semiconductor layer 22p may be formed.

The p⁺ semiconductor layer 22p or the n⁺ semiconductor layer 22n forming the rectifying element 22 may be formed from a semiconductor material such as silicon (Si), silicon germanium (SiGe), silicon carbide (SiC), germanium (Ge), carbon (C), or the like. The p⁺ semiconductor layer 22p or the n⁺ semiconductor layer 22n may be formed from a polycrystalline material, or a monocrystalline material.

The silicide used in the bonding portion between the p⁺ semiconductor layer 22p or the n⁺ semiconductor layer 22n forming the rectifying element 22, and the lower electrode 21, or the cathode electrode 24, or the anode electrode 26 may be formed using scandium (Sc), titanium (Ti), vanadium (V), chromium (Cr), manganese (Mn), iron (Fe), cobalt (Co), nickel (Ni), copper (Cu), zinc (Zn), rhodium (Rh), lead (Pb), silver (Ag), cadmium (Cd), indium (In), tin (Sn), lanthanum (La), hafnium (Hf), tantalum (Ta), tungsten (W), rhenium (Re), osmium (Os), iridium (Ir), platinum (Pt), gold (Au), or the like.

Furthermore, the above silicides may include the addition of one or more elements selected from the group consisting of scandium (Sc), titanium (Ti), vanadium (V), chromium (Cr), manganese (Mn), iron (Fe), cobalt (Co), nickel (Ni), copper (Cu), yttrium (Y), zirconium (Zr), niobium (Nb), molybdenum (Mo), technetium (Tc), ruthenium (Ru), rhodium (Rh), lead (Pb), silver (Ag), cadmium (Cd), indium (In), tin (Sn), lanthanum (La), hafnium (Hf), tantalum (Ta), tungsten (W), rhenium (Re), osmium (Os), iridium (Ir), platinum (Pt), gold (Au), or the like.

The insulating layer 22i forming the rectifying element 22 for example may be formed from an oxide, oxynitride, nitride, or the like.

The oxide for example, includes silicon oxide (SiO₂), aluminum oxide (Al₂O₃), yttrium oxide (Y₂O₃), lanthanum oxide (La₂O₃), gadolinium oxide (Gd₂O₃), cerium (III) oxide (Ce₂O₃), cerium oxide (CeO₂), tantalum oxide (Ta₂O₅), hafnium oxide (HfO₂), zirconium oxide (ZrO₂), titanium oxide (TiO₂), hafnium silicate (HfSiO), hafnium aluminate (HfAlO), zirconium silicate (ZrSiO), zirconium aluminate (ZrAlO), aluminum silicate (AlSiO), or the like.

An oxide may also be represented as “AB₂O₄”.

In this case, “A” and “B” may be the same element or different elements, and for example include aluminum (Al), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), and the like.

For example, the oxide may include iron (III) oxide (Fe₃O₄), hercynite (FeAl₂O₄), Mn₁₊ₓAl₂₋ₓO_{4+y}, Co₁₊ₓAl₂₋ₓO_{4+y}, MnOₓ, or the like.

An oxide may also be represented as “ABO₃”.

In this case, “A” and “B” may be the same element or different elements, and for example include aluminum (Al), lanthanum (La), hafnium (Hf), tantalum (Ta), tungsten (W), rhenium (Re), osmium (Os), iridium (Ir), platinum (Pt), gold (Au), mercury (Hg), thallium (TI), lead (Pb), bismuth (Bi), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), yttrium (Y), zirconium (Zr), niobium (Nb), molybdenum (Mo), technetium (Tc), ruthenium (Ru), rhodium (Rh), lead (Pb), silver (Ag), cadmium (Cd), indium (In), tin (Sn), and the like.

For example, the oxide may include lanthanum aluminate (LaAlO₃), strontium hafnate (SrHfO₃), strontium zirconate (SrZrO₃), strontium titanate (SrTiO₃), and the like.

The oxynitride for example, includes silicon oxynitride (SiON), aluminum oxynitride (AlON), yttrium oxynitride (YON), lanthanum oxynitride (LaON), gadolinium oxynitride (GdON), cerium oxynitride (CeON), tantalum oxynitride (TaON), hafnium oxynitride (HfON), zirconium oxynitride (ZrON), titanium oxynitride (TiON), LaAlON, SrHfON, SrZrON, SrTiON, hafnium silicate (HfSiON), HfAlON, ZrSiON, ZrAlON, AlSiON, or the like.

The nitride may substitute the oxygen atoms in the above oxide compounds with nitrogen atoms.

Although the insulating layer 22i in the example shown in FIG. 2 is formed as a single layer, it may be formed from multiple layers having a different electron barrier height and/or a different dielectric constant.

In this configuration, the insulating layer 22i is particularly preferably formed from silicon oxide (SiO₂), silicon nitride (SiN, Si₃N₄), aluminum oxide (Al₂O₃), silicon oxynitride (SiON), hafnium oxide (HfO₂), HfSiON, tantalum oxide (Ta₂O₅), titanium oxide (TiO₂), strontium titanate (SrTiO₃), or the like.

Silicon-based materials such as silicon oxide (SiO₂), silicon nitride (SiN, Si₃N₄), silicon oxynitride (SiON), or the like may have a concentration of oxygen atoms or nitrogen atoms at a respective concentration of at least 1×10¹⁸/cm³.

The insulating layer 22i may be formed from a material including impurity atoms that form a defect level, or a semiconductor/metal dot (quantum dot).

A rectifying element having the above configuration can be adapted as a non-ohmic element that enables miniaturization and low-temperature formation.

Next, an example of the operation of the rectifying element according to the embodiment will be further described.

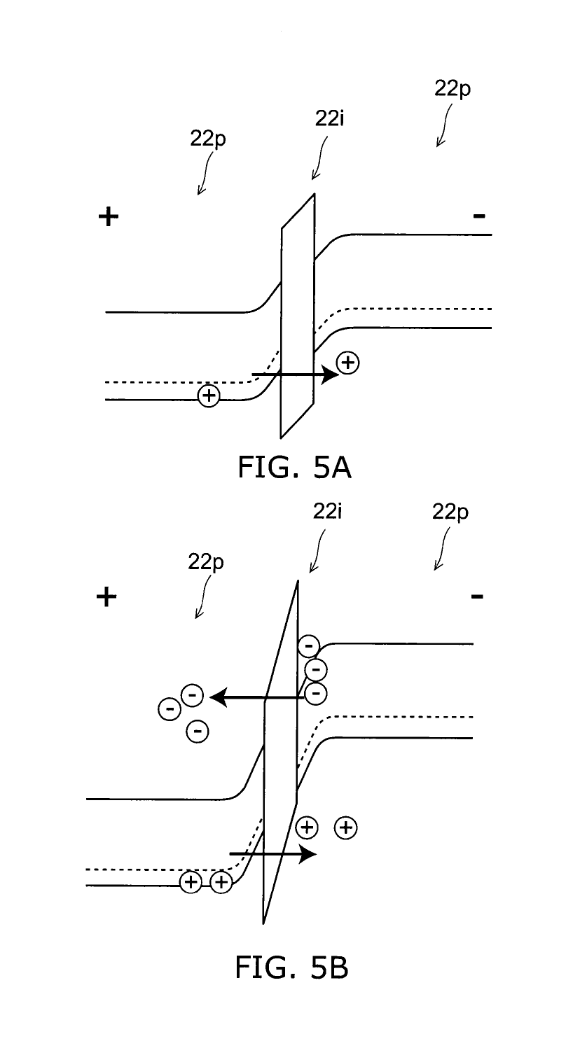

FIGS. 5A and 5B show a schematic view illustrating an energy band of the rectifying element according to the embodiment. FIG. 5A shows the operation under a weak voltage, and FIG. 5B shows the operation during application of a bias. FIGS. 5A and 5B illustrate an example in which the rectifying element 22 is formed from a p⁺ semiconductor layer 22p-insulating layer 22i-p⁺ semiconductor layer 22p.

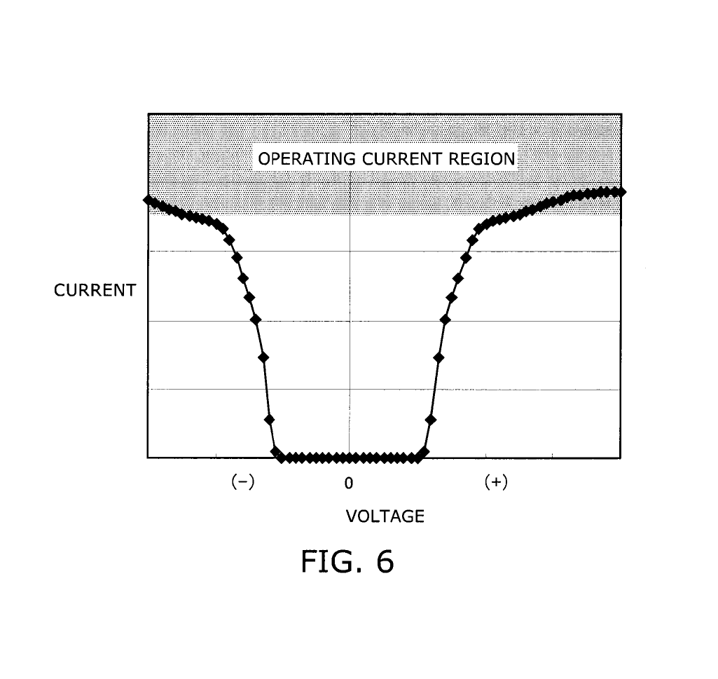

FIG. 6 is a schematic graph illustrating the current-voltage characteristics of the rectifying element according to the embodiment.

As shown in FIG. 5A, during application of weak voltage, although positive-hole current is thought to flow as a result of a direct tunnel, almost no current flows since the number of carriers (positive holes) is low. Furthermore the impurity concentration can be adapted to reduce the number of carriers.

On the other hand, as shown in FIG. 5B, when a bias is applied, a band inversion causes an increase in the carrier concentration, and a sharp current increase is caused by an F-N (Fowler-Nordheim) tunnel.

In a general pin diode (p semiconductor layer-intrinsic semiconductor-n semiconductor layer), a current is caused by the carriers in the p semiconductor layer and the n semiconductor layer. As a result, since immediate current flows due to application of a bias, the ON/OFF ratio cannot be increased.

In contrast, the rectifying element according to the embodiment produces a band inversion due to application of a bias that increases the carrier concentration and sharply increases the current.

As a result, as shown in FIG. 6, although current flows when the predetermined reference voltage Vth region is reached, current flow at a lower voltage can be suppressed. In addition, a large reduction in the OFF current or the reverse current is enabled due to the effect of the insulating layer. In other words, a configuration is enabled that is characterized by a large ON/OFF ratio and rapid build-up.

The reference voltage Vth region can also be varied to enable current to flow as a result of the doping amount in the semiconductor layer. As a result, characteristics such as a large ON/OFF ratio or rapid build-up can be varied by the doping amount in the semiconductor layer.

Next, an example of a variation of the rectifying element according to the embodiment will be described.

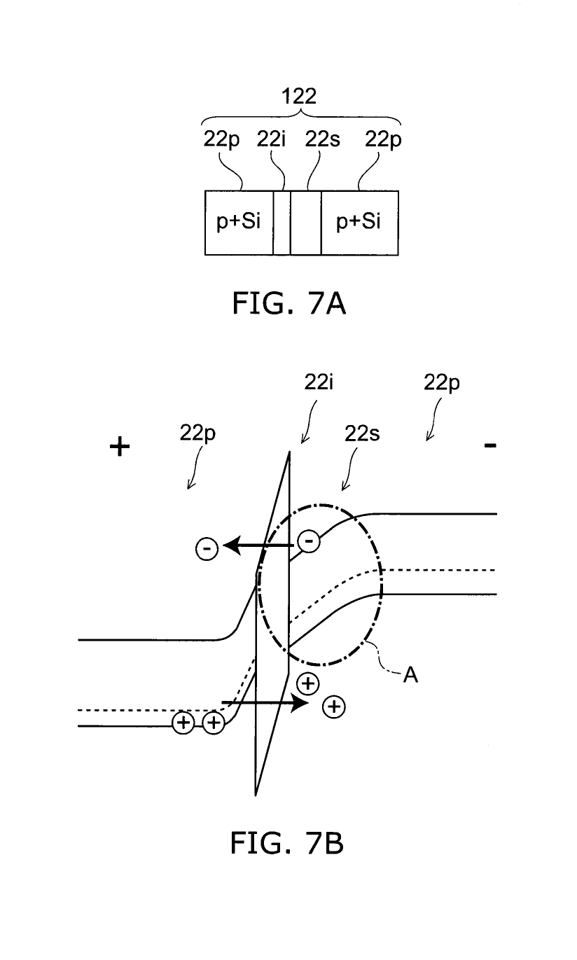

FIG. 7A is a schematic view illustrating the configuration of the rectifying element according to a first variation. FIG. 7B is a schematic view illustrating the energy band during application of bias to the rectifying element according to the first variation.

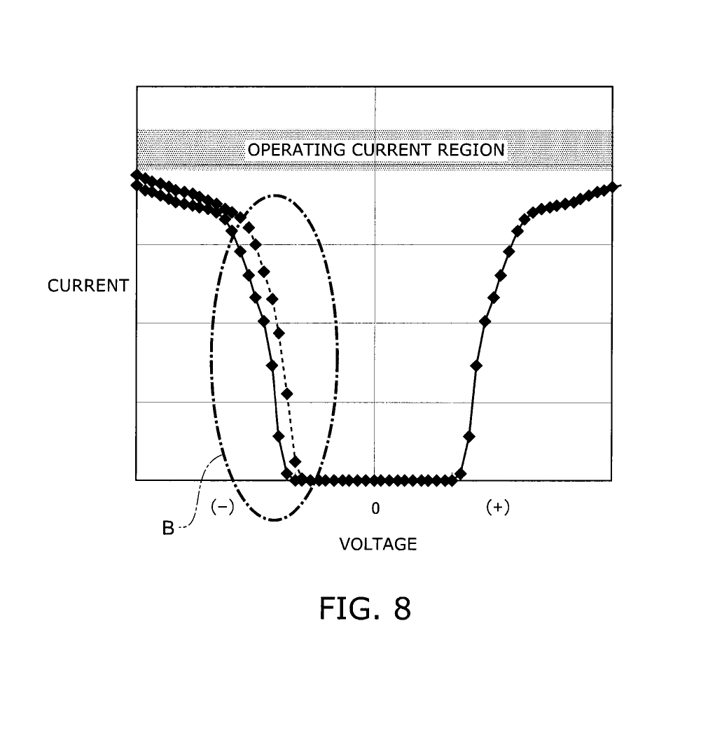

FIG. 8 is a schematic graph illustrating the current-voltage characteristics according to the first variation.

As shown in FIG. 7A, the rectifying element 122 is formed by stacking a p⁺ semiconductor layer 22p, an insulating layer 22i, an intrinsic semiconductor (for example, intrinsic Si) 22s, and a p⁺ semiconductor layer 22p. In other words, in comparison to the rectifying element 22 above, an intrinsic semiconductor layer 22s that has a low impurity concentration is provided between one p⁺ semiconductor layer 22p and the insulating layer 22i.

In comparison to the rectifying element 22 above, the provision of the intrinsic semiconductor layer 22s enables a voltage that increases the electron concentration on the side including the intrinsic semiconductor layer 22s to retard (a voltage associated with current flow to increase). As a result, in portion A as shown in FIG. 7B, the curvature that shows the energy band on the side including the intrinsic semiconductor layer 22s can be reduced in proximity to the insulating layer 22i.

The term intrinsic semiconductor layer here also includes an n⁻ semiconductor layer and a p⁻ semiconductor layer doped with 10¹⁸/cm³ or less.

The provision of the intrinsic semiconductor layer 22s can suppress diffusion of doped impurities from the p⁺ semiconductor layer 22p or the n⁺ semiconductor layer 22n into the insulating layer 22i.

In this manner, as shown by portion B in FIG. 8, manipulation of the voltage that increases the electron concentration enables voltage that builds up current to shift in a direction that increases the region in which current does not flow. Consequently, in the bipolar operation, the range of the V/2 setting as described above can be increased. Therefore, although the central axis of the current-voltage characteristics deviates from a 0 V (volt) orientation, adjustment may be performed by changing the biasing method or the like.

The ON/OFF ratio can be adjusted by arbitrarily varying the current-voltage characteristics with the thickness of the intrinsic semiconductor layer 22s. Thus, adaptation to the specification for current-voltage characteristics required by circuit design is possible by varying the thickness of the intrinsic semiconductor layer 22s without varying the applied bias.

Although the rectifying element 122 shown in FIG. 7A includes an intrinsic semiconductor layer 22s on one side of the insulating layer 22i, the intrinsic semiconductor layer 22s may be provided on both sides of the insulating layer 22i. In this manner, the region without current can be further increased. Thus, in the bipolar operation, the range of the V/2 setting as described above can be increased. Therefore, since the range in which the current-voltage characteristics can be arbitrarily varied is increased, adjustment of the ON/OFF ratio is simplified. Thus, adaptation to the specification for current-voltage characteristics required by circuit design is further simplified.

Although FIG. 5A to FIG. 8 illustrate a rectifying element that has a p⁺ semiconductor layer-insulating layer-p⁺ semiconductor layer configuration, a rectifying element is similarly obtained by an n⁺ semiconductor layer-insulating layer-n⁺ semiconductor layer configuration, or a p⁺ semiconductor layer-insulating layer-n⁺ semiconductor layer configuration. In this case, the p⁺ semiconductor layer-insulating layer-p⁺ semiconductor layer configuration or the n⁺ semiconductor layer-insulating layer-n⁺ semiconductor layer configuration is suitably applied to the bipolar operation. The p⁺ semiconductor layer-insulating layer-n⁺ semiconductor layer configuration is suitable applied to the unipolar operation.

In the above description, the insulating layer 22i is a single layer.

Next, a second variation of the rectifying element will be described in which the insulating layer is formed from multiple layers having a different electron barrier height and/or a different dielectric constant.

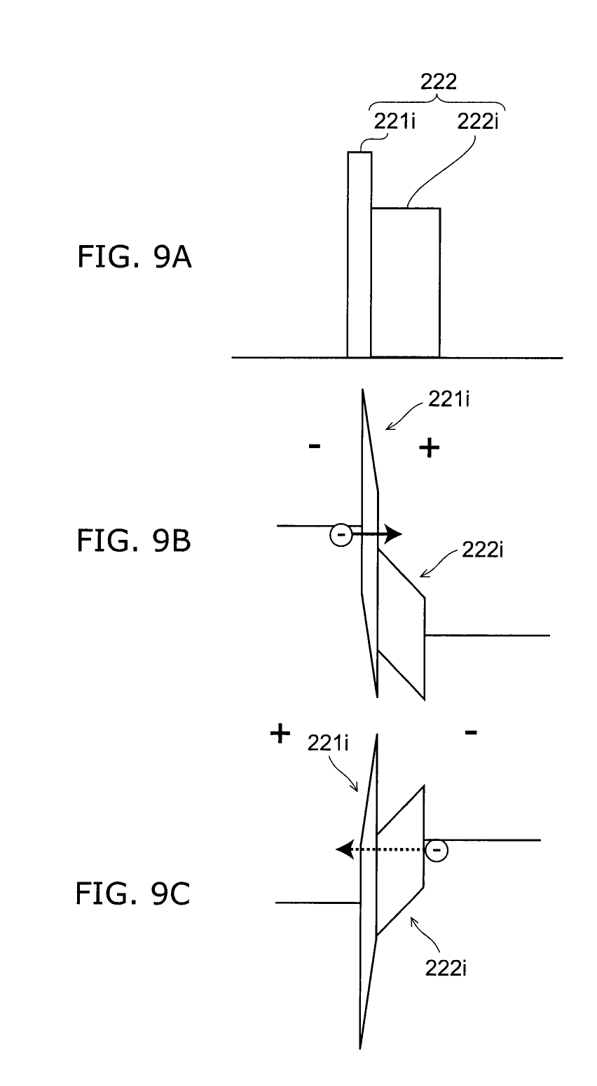

FIG. 9A is a schematic view illustrating the insulating layer formed from multiple layers having a different electron barrier height, and FIGS. 9B and 9C are schematic views illustrating electron passage.

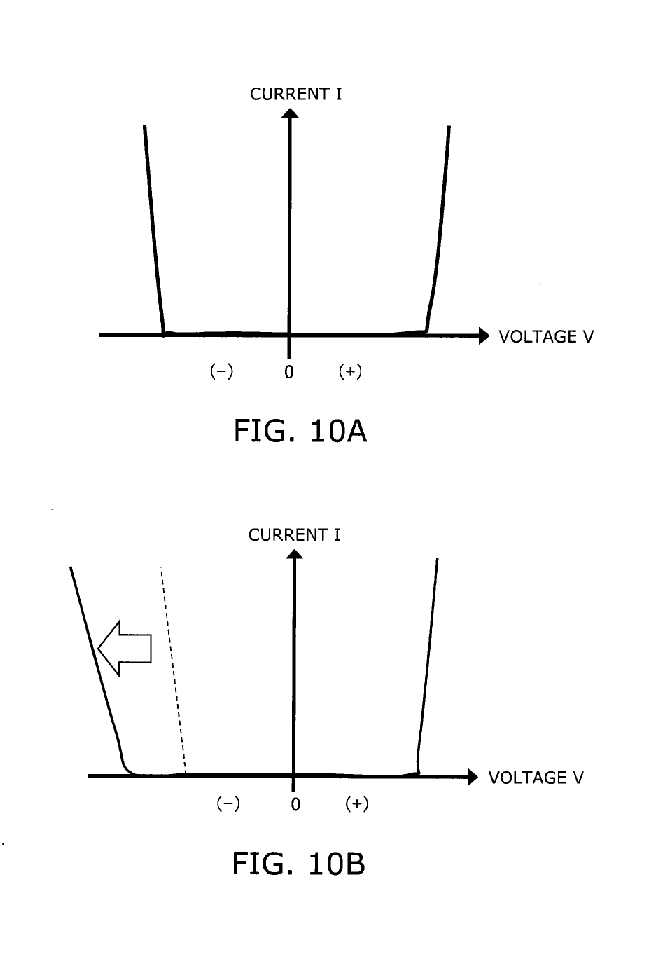

FIG. 10A is a schematic graph illustrating the current-voltage characteristics when the insulating layer is a single layer, and FIG. 10B is a schematic graph illustrating the current-voltage characteristics when the insulating layer is formed from multiple layers.

As shown in FIG. 9A, an insulating layer 222 is configured from an insulating layer 221i and an insulating layer 222i that have different electron barrier heights. For example, one layer is an insulating layer formed from silicon oxide and the other layer is an insulating layer formed from silicon nitride. In this configuration, the electron barrier height of the insulating layer 221i is greater than the electron barrier height of the insulating layer 222i.

As shown in FIG. 9B, when an electron passes from the insulating layer 221i that has a large electron barrier height, the electron passes through the insulating layer 222 by traversing only the electron barrier of the insulating layer 221i.

On the other hand, as illustrated in FIG. 9C, when an electron passes from the insulating layer 222i that has a low electron barrier height, the electron cannot pass through the insulating layer 222 unless it traverses both the electron barrier of the insulating layer 221i and the insulating layer 222i.

In other words, passage of electrons from the insulating layer 221i that has a high electron barrier is facilitated and passage of electrons from the insulating layer 222i that has a low electron barrier is impeded.

Although the example shows electron barriers having different heights, the situation is the same as the case where the dielectric constant is different. In the general material, an electron barrier tends to lower with increasing dielectric constant of insulator, therefore it is unchanged that carriers are easier to flow from a low electron barrier side.

Thus, when the insulating layer is a single layer, the current-voltage characteristics are obtained that are substantially symmetrical about 0 V (volts) as shown in FIG. 10A.

On the other hand, when the insulating layer is formed from multiple layers having a different electron barrier height and/or a different dielectric constant, as illustrated in FIG. 10B, the voltage that builds up current can be shifted in a direction that increases the region in which current does not flow. Consequently, in the bipolar operation, the range of the V/2 setting as described above can be increased. Although the central axis of the current-voltage characteristics shifts from a 0 V (volt) position, adjustment may be performed by changing the biasing method or the like.

Furthermore, adjustment of the ON/OFF ratio is possible since the current-voltage characteristics can be arbitrarily varied by varying the height of the electron barrier and/or the dielectric constant. Thus, adaptation to the specification for the current-voltage characteristics required by circuit design is possible by varying the height of the electron barrier and/or the dielectric constant without varying the applied bias.

The configuration shown in FIGS. 9A and 9B illustrates the insulating layer formed from two layers having different electron barrier heights and/or dielectric constants. However, the insulating layer can also be formed from three layers or more having different electron barrier heights and/or dielectric constants.

Use of the rectifying element illustrated above obtains the following effects. (1) Reverse current (current in the opposite direction) or the OFF current can be suppressed in comparison to a general pin diode (p semiconductor layer-intrinsic semiconductor layer-n semiconductor layer). In addition, the thickness of the rectifying element can be reduced approximately by ½-⅓. This feature means that if the same applied voltage and the same thickness as those for the general pin diode are used for the rectifying element of the embodiment, reverse current (current in the opposite direction) or the OFF current can be drastically reduced in comparison to a general pin diode (p semiconductor layer-intrinsic semiconductor layer-n semiconductor layer). Therefore, reduction in power consumption, an improvement in operational speed, and an improvement in READ (reading) operations are enabled.

In the rectifying element used in the nonvolatile semiconductor memory device, sufficient suppression of the OFF current, or the reverse current (current in the opposite direction) is required during SET (program)/RESET (erase) to thereby enable stable SET (program)/RESET (erase) operations. For that purpose, when using a general pin diode (p semiconductor layer-intrinsic semiconductor layer-n semiconductor layer) the thickness thereof must be substantially of the level of 100 nm (nanometers)-150 nm (n a no meters).

In contrast, the rectifying element according to the embodiment may be configured as a p⁺ semiconductor layer 22p (thickness 5 nm (nanometers))-intrinsic semiconductor layer 22s (thickness 20 nm (nanometers))-insulating layer 22i (thickness 1 nm (nanometers))-intrinsic semiconductor layer 22s (thickness 20 nm (nanometers))-p⁺ semiconductor layer 22p (thickness 5 nm (nanometers)).

In other words, the thickness of the rectifying element according to the embodiment can be limited to the range of 25 nm (nanometers) to 100 nm (nanometers). This feature means that the aspect ratio can be improved by ½-⅓.

(2) Since both sides of the insulating layer 22i are used in common in the semiconductor layer, rectifying characteristics can be controlled by varying the Fermi potential Ef of the semiconductor layer. In this configuration, the Fermi potential Ef on the electron injection side is set to a high potential (for example, n⁺ side), and the Fermi potential Ef on the electron accepting side is set to a low potential (for example, p⁺ side), Thereby the current-voltage characteristics are asymmetrical in the right-left direction. For this reason, in the bipolar operation, the effects described above such as increasing the range of the V/2 setting can be obtained.

(3) Since both sides of the insulating layer 22i can be used in common in the semiconductor layer, when both sides are configured as a p⁺ semiconductor layer 22p, rectifying characteristics can be controlled by providing an intrinsic semiconductor layer 22s. Furthermore, the value of the reference voltage Vth can be configured to take different values on the + side and the − side by providing an intrinsic semiconductor layer 22s that has a different thickness on both sides of the insulating layer 22i. In other words, the build-up of the reference voltage Vth can be configured asymmetrically. For example, when using a configuration of a p⁺ semiconductor layer 22p (thickness 5 nm (nanometers))-intrinsic semiconductor layer 22s (thickness 10 nm (nanometers))-insulating layer 22i-intrinsic semiconductor layer 22s (thickness 20 nm (nanometers))-p⁺ semiconductor layer 22p (thickness 5 nm (nanometers)), the electrical field is relaxed in thicker portions of the intrinsic semiconductor layer 22s, and thus voltage build-up can be retarded. Therefore, the value taken by the reference voltage Vth can be configured to be different on the + side and the − side, and thus control of the reverse current (current in the opposite direction) or the OFF current is possible.

Provision of an intrinsic semiconductor layer 22s can suppress diffusion of doped impurities from the p⁺ semiconductor layer 22p or the n⁺ semiconductor layer 22n into the insulating layer 22i.

(4) When the insulating layer is formed from multiple layers having a different electron barrier height and/or a different dielectric constant, adjustment of the ON/OFF ratio is enabled even in the absence of adjustment of the impurity concentration in the semiconductor layer. Therefore, since adjustment of the ON/OFF ratio is possible using the two methods of adjustment of the impurity concentration in the semiconductor layer and the configuration of the insulating layer, adaptation to the specification for the current-voltage characteristics required by circuit design is facilitated.

Next, a third variation of the rectifying element will be described.

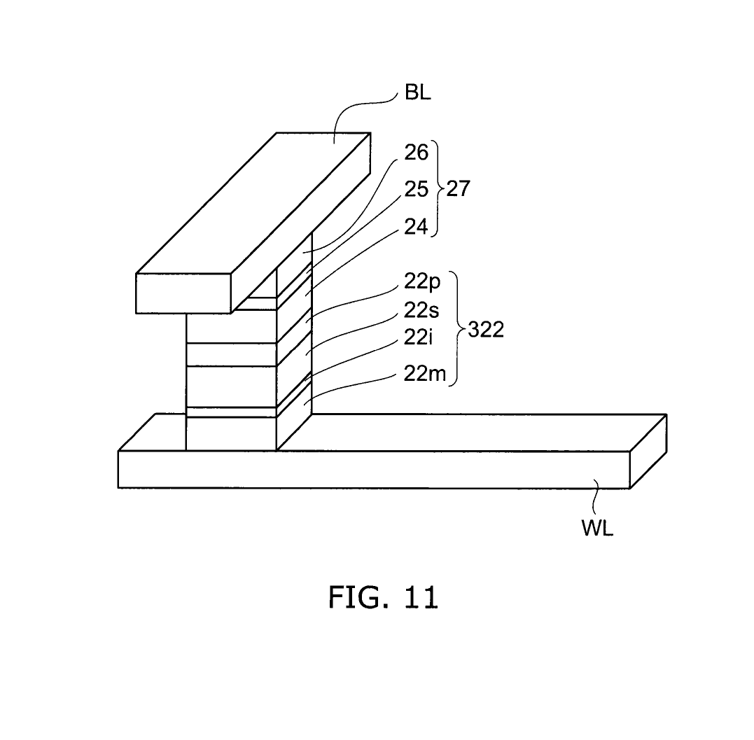

FIG. 11 is a schematic perspective view illustrating the configuration of the rectifying element according to the third variation.

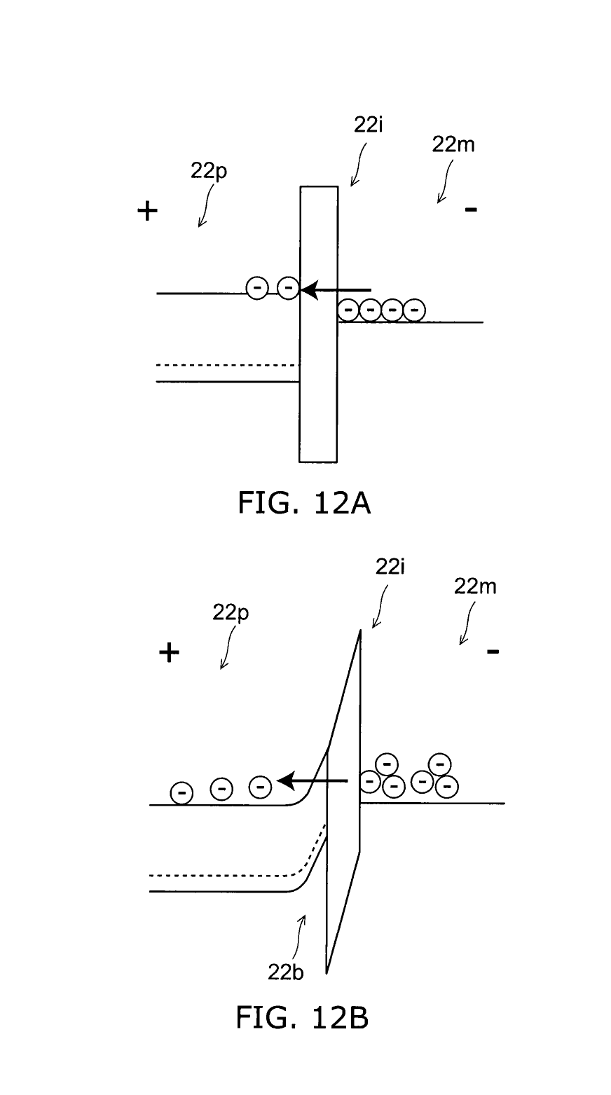

FIGS. 12A and 12B are schematic views illustrating the energy band during application of a bias to the forward side. FIG. 12A illustrates the operation during application of a weak voltage, and FIG. 12B illustrates the operation when a higher voltage is applied.

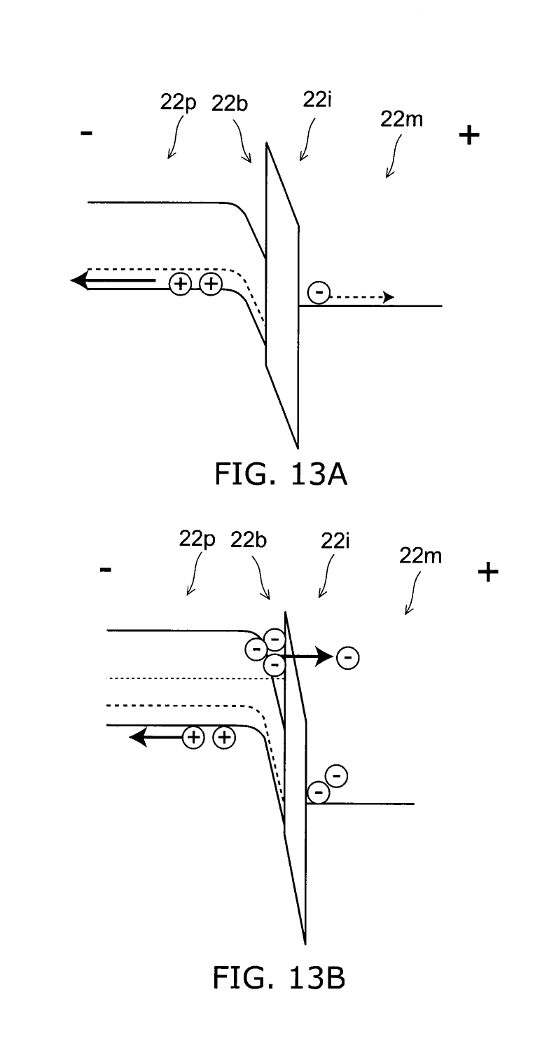

FIGS. 13A and 13B are schematic views illustrating the energy band during application of a bias to the reverse side. FIG. 13A illustrates the operation during application of a weak voltage, and FIG. 13B illustrates the operation when a higher voltage is applied.

As shown in FIG. 11, the rectifying element 322 according to the third variation is configured by stacking the metal layer 22m, the insulating layer 22i, the intrinsic layer 22s, and the p⁺ semiconductor layer 22p (third semiconductor layer). In other words, the metal layer 22m is provided in substitution for one of the p⁺ semiconductor layers 22p in the rectifying element 122 described above. In this configuration, a Schottky junction (Schottky barrier) 22b is formed when there is a difference between the work function WF of the metal layer 22m and the Fermi potential Ef of the portion on the metal layer 22m side of the p⁺ semiconductor layer 22p.

The metal layer 22m may be formed by a single metal element or a mixture of multiple metal elements, a silicide or oxide, or a nitride. For example, it may be formed from the same material as the cathode electrode 24 or anode electrode 26 described above.

In this manner, provision of the metal layer 22m on one side increases the number of carriers, and enables the ON current to be increased.

When the work function WF of the metal layer 22m is adjusted, the same current-voltage characteristics are obtained as the rectifying element described above in which the p⁺ semiconductor layer 22p and the p⁺ semiconductor layer 22p are opposed to sandwich the insulating layer 22i.

The rectifying element 322 having the above configuration may be suitably applied to either unipolar operation or bipolar operation.

When 0 V (volt) is taken to be the central axis, the current-voltage characteristics are configured asymmetrically. However the same operation as the rectifying element 122 described above is possible by variation of the bias method.

An example of the operation of the rectifying element 322 will be described below.

When a bias is applied to the forward side, a current flows through a direct tunnel of electrons as illustrated in FIG. 12A during application of a weak voltage (for example, of the level of 1 V). As shown in FIG. 12B, when a higher voltage is applied, the electron concentration is increased, and current flowing through the F-N (Fowler-Nordheim) tunnel increases.

When bias is applied on the reverse side, almost no current flow as a result of the low number of carriers as shown in FIG. 13A during application of a weak voltage (for example, of the level of 1 V). In this configuration, when a higher voltage is applied, as illustrated in FIG. 13B, the energy band curves, the electron concentration increases, and thereby the number of carriers (electrons) increases. Consequently, current flow through the F-N (Fowler-Nordheim) tunnel is increased.

Although the example of the insulating layer 22i is illustrated as a single layer, the insulating layer 22i may be formed from multiple layers having a different electron barrier height and/or a different dielectric constant in the same manner as the rectifying element described above. For example, a configuration such as “S-I1-I2-M”, “S-I1-I2-I3-M”, “S-I1-I 2-M-S”, “S-I1-I2-I3-M-S”, or the like is possible. As used herein, S denotes a semiconductor layer (p⁺ semiconductor layer 22p or n⁺ semiconductor layer 22n), I1 through I3 denote an insulating layer, and M denotes the metal layer 22m.

Since the configuration of the insulating layer formed from multiple layers having a different electron barrier height and/or a different dielectric constant is the same as the configuration described above, description will be omitted.

Although an intrinsic semiconductor layer 22s has been provided as an example, the intrinsic semiconductor layer 22s may be provided as required. Provision of the intrinsic semiconductor layer 22s obtains the effects in (3) described below.

The following effects are obtained by use of the rectifying element 322 described in the embodiment.

(1) In comparison to a general pin diode (p semiconductor layer-intrinsic semiconductor layer-n semiconductor layer), reverse current (current in the opposite direction) or the OFF current can be suppressed. In addition, the thickness of the rectifying element can be reduced by ½ through ⅓. As a result, in the same manner as the rectifying element described above, the aspect ratio can be improved by ½ through ⅓, and processing is thereby facilitated. This means that when the same applied voltage and the same thickness as those for the general pin diode are used for the rectifying element of the embodiment, reverse current (current in the opposite direction) or the OFF current can be drastically reduced in comparison to a general pin diode (p semiconductor layer-intrinsic semiconductor layer-n semiconductor layer). Therefore, reduction in power consumption, improvement in operational speed, and improvement in READ (reading) operations are enabled.

(2) Since one side of the insulating layer 22i is configured as a semiconductor layer (a p⁺ semiconductor layer or an n⁺ semiconductor layer) and the other side is configured as a metal layer 22m, rectifying characteristics can be controlled by varying the Fermi potential Ef of the semiconductor layer and the metal layer 22m. In this configuration, the Fermi potential Ef on the electron injection side is set to a high potential (for example, n⁺ side), and the Fermi potential Ef on the electron accepting side is set to a low potential (for example, p⁺ side), thereby the current-voltage characteristics are asymmetrical in the right-left direction.

(3) Rectifying characteristics can be controlled by providing an intrinsic semiconductor layer 22s between the insulating layer 22i and the p⁺ semiconductor layer or the n⁺ semiconductor layer provided on one side of the insulating layer 22i. Furthermore, the value of the reference voltage Vth can be configured to take different values on the + side and the − side by providing the intrinsic semiconductor layers 22s with a different thickness on both sides of the insulating layer 22i. In other words, the build-up of the reference voltage Vth can be configured asymmetrically. For example, when using a configuration of a p⁺ semiconductor layer 22p (thickness 5 nm (nanometers))-intrinsic semiconductor layer 22s (thickness 20 nm (nanometers))-insulating layer 22i-metal layer 22m, the electrical field is relaxed on the side provided with the intrinsic semiconductor layer 22s, and thus voltage build-up can be retarded. Therefore, the value taken by the reference voltage Vth can be configured to be different on the + side and the − side, and thus control of the reverse current (current in the opposite direction) or the OFF current is possible.

Provision of an intrinsic semiconductor layer 22s can suppress diffusion of doped impurities from the p⁺ semiconductor layer 22p or the n⁺ semiconductor layer 22n into the insulating layer 22i.

(4) When the insulating layer is formed from multiple layers having a different electron barrier height and/or a different dielectric constant, adjustment of the ON/OFF ratio is enabled even in the absence of adjustment of the impurity concentration in the semiconductor layer. Therefore, since adjustment of the ON/OFF ratio is possible using the two methods of adjustment of the impurity concentration in the semiconductor layer and the configuration of the insulating layer, adaptation to the specification for the current-voltage characteristics required by circuit design is facilitated.

Next, a fourth variation of the rectifying element will be described.

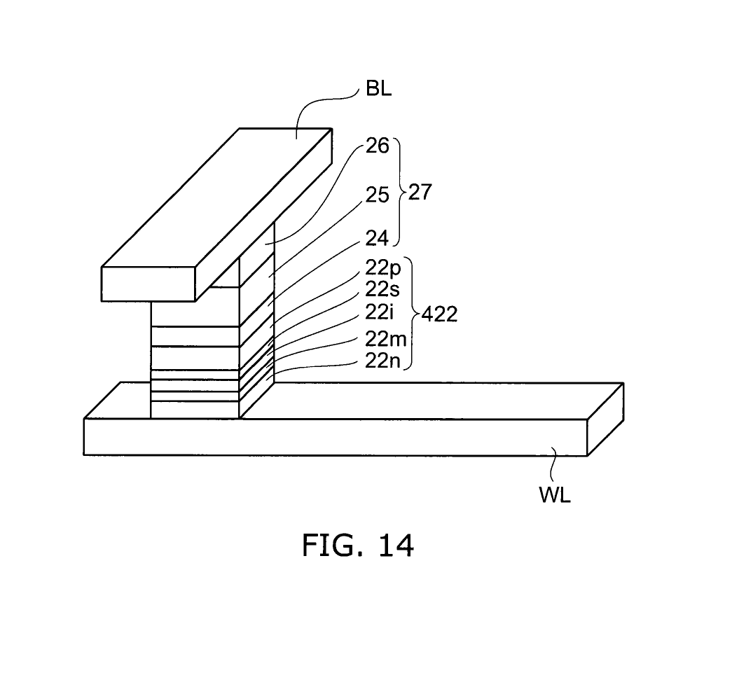

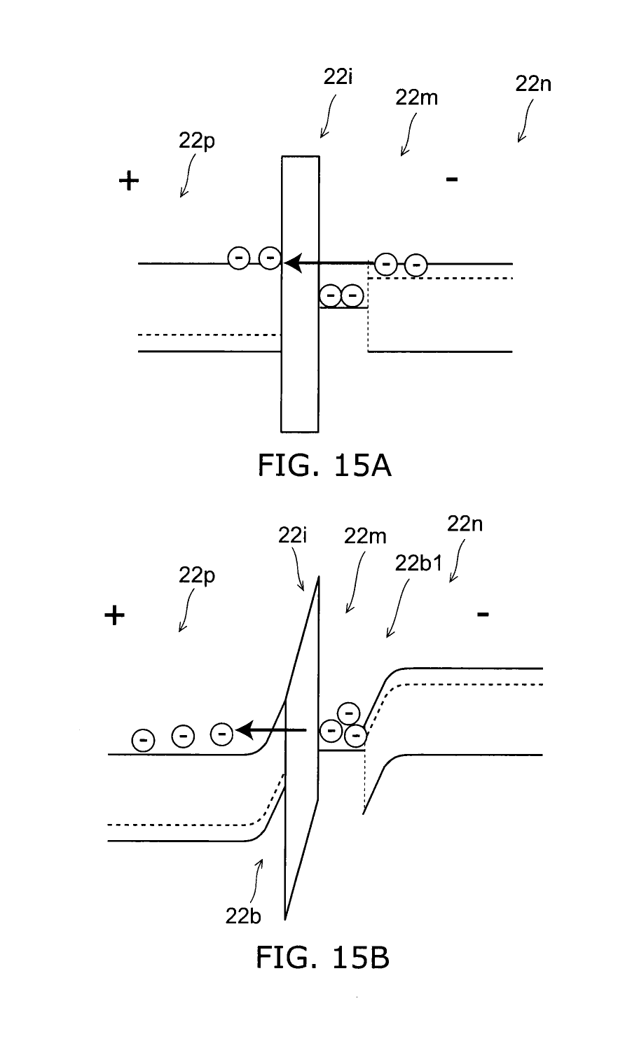

FIG. 14 is a schematic perspective view illustrating the configuration of the rectifying element according to the fourth variation. FIGS. 15A and 15B are schematic view of the energy band during application of a bias to the forward side. FIG. 15A illustrates the operation during application of a weak voltage, and FIG. 15B illustrates the operation when a higher voltage is applied.

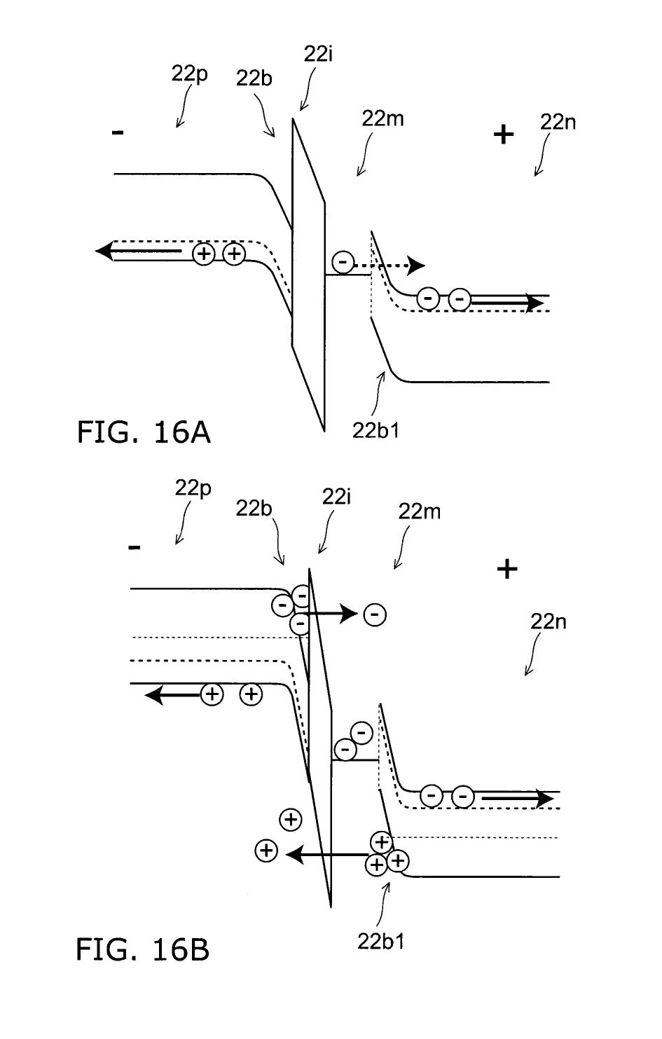

FIGS. 16A and 16B are schematic views illustrating the energy band during application of a bias to the reverse side. FIG. 16A illustrates the operation during application of a weak voltage, and FIG. 16B illustrates the operation when a higher voltage is applied.

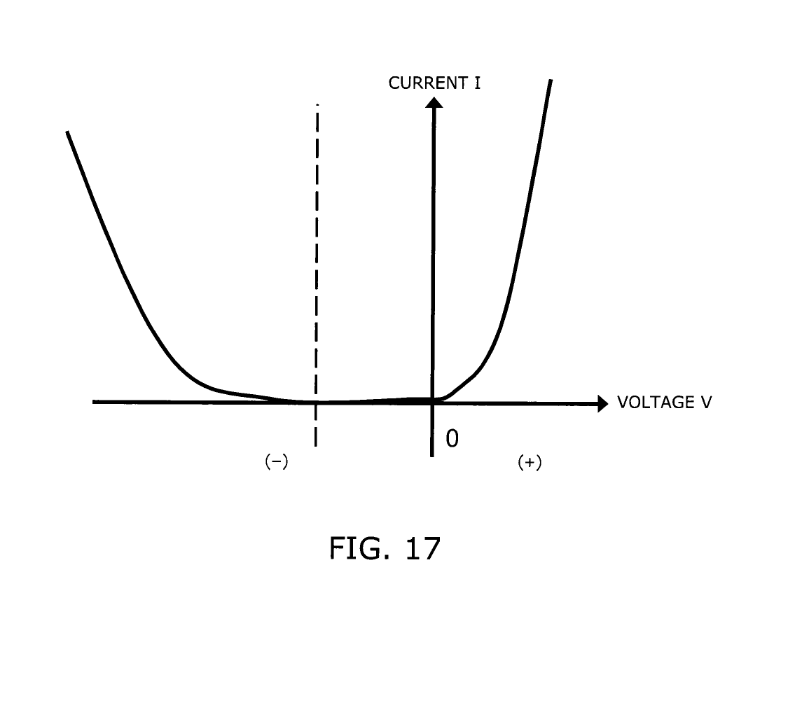

FIG. 17 is a schematic graph illustrating the current-voltage characteristics of the rectifying element according to the fourth variation.

As shown in FIG. 14, the rectifying element 422 according to the fourth variation is configured by stacking the n⁺ semiconductor layer 22n (fourth semiconductor layer), the metal layer 22m, the insulating layer 22i, the intrinsic layer 22s, and the p⁺ semiconductor layer 22p. In other words, in comparison to the rectifying element 322 described above, an additional n⁺ semiconductor layer 22n is provided on the side opposite to the side provided with the insulating layer 22i for the metal layer 22m. A p⁺ semiconductor layer 22p can also be provided in substitution for the n⁺ semiconductor layers 22n. Furthermore the n⁻ semiconductor layer can also be provided in substitution for the intrinsic layer 22s. For example, it may be the case that a further p⁺ semiconductor layer 22p or n⁺ semiconductor layer 22n is provided in the rectifying element 322 described above. In this configuration, a Schottky junction (Schottky barrier) 22b1 is formed when there is a difference between the work function WF of the metal layer 22m and the Fermi potential Ef of the portion on the metal layer 22m side of the n⁺ semiconductor layer 22n (or the p⁺ semiconductor layer 22p). In other words, a Schottky junction 22b1 is formed in addition to the Schottky junction 22b described above. For this reason, fine adjustment of the current-voltage characteristics is facilitated.

The operation of the rectifying element 422 will be described below.

When a bias is applied to the forward side, a current of electrons flows through a direct tunnel as illustrated in FIG. 15A during application of a weak voltage (for example, of the level of 1V). As shown in FIG. 15B, when a higher voltage is applied, the electron concentration is increased, and current flow through the F-N (Fowler-Nordheim) tunnel is increased.

When a bias is applied to the reverse side, the low number of carriers as shown in FIG. 16A results in almost no current flow during application of a weak voltage (for example, of the level of 1V). In this configuration, when a higher voltage is applied, as illustrated in FIG. 16B, the energy band becomes curved, the electron concentration increases, and thereby the number of carriers (electrons) increases. Consequently, current flow through the F-N (Fowler-Nordheim) tunnel is increased.

Although the insulating layer 22i is illustrated as a single layer, the insulating layer 22i may be formed from multiple layers having a different electron barrier height and/or a different dielectric constant in the same manner as the rectifying element described above. For example, a configuration such as “S-I1-I2-M”, “S-I1-I2-I 3-M”, “S-I1-I 2-M-S”, “S-I1-I2-I3-M-S”, or the like is possible. As used herein, S denotes a semiconductor layer (p⁺ semiconductor layer 22p or n⁺ semiconductor layer 22n), I1-I3 denote the insulating layer 22i, and M denotes the metal layer 22m.

Since the configuration of the insulating layer formed from multiple layers having a different electron barrier height and/or a different dielectric constant is the same as the configuration described above, the description will be omitted.

A memory function may be added to the insulating layer 22i.

In other words, the memory portion 27 may be incorporated into an inner portion of the rectifying element 422.

In particular, when using a p⁺ semiconductor layer 22p-metal layer 22m-insulating layer 22i-intrinsic semiconductor layer 22s (or n⁻ semiconductor layer)-p⁺ semiconductor layer 22p configuration, since the intrinsic semiconductor layer 22s (or n⁻ semiconductor layer) is disposed between the p⁺ semiconductor layer 22p and the insulating layer 22i, the insulating layer 22i operates as a memory in the ON state, and even when insulative properties are lost, since a function as a pnp bipolar transistor is enabled, the OFF current can be suppressed. In this configuration, although the OFF current fluctuates in response to placing the memory portion (including the insulating layer 22i) in the ON or OFF position, the OFF current can be suppressed by varying the bias method.

The rectifying element 422 according to the embodiment obtains the same effect as the rectifying element 322 described above.

However, when a semiconductor layer-insulating layer-metal layer-semiconductor layer configuration is used, in addition to the effect obtained by the rectifying element 322, the additional effect of the Schottky junction 22b1 is obtained. In other words, since the Schottky junction 22b1 is formed in addition to the Schottky junction 22b, another control element for the current-voltage characteristics is available, and thereby further facilitates the fine adjustment of the current-voltage characteristics. Furthermore, although advantages in relation to the aspect ratio are adversely affected by the addition of a further metal layer 22m, any effect on thickness reduction can be said to be minimal.

When a semiconductor layer-metal layer-insulating layer-metal layer-semiconductor layer configuration is used, even when the memory portion is in an ON state (state without insulative properties), the OFF current can be suppressed by the action of the Schottky junction. In this configuration, although advantages in relation to the aspect ratio are adversely affected by the addition of a further semiconductor layer, any effect on thickness reduction can be said to be minimal. Furthermore, when an intrinsic semiconductor layer 22s is provided, diffusion of doped impurities from the p⁺ semiconductor layer 22p or the n⁺ semiconductor layer 22n into the insulating layer 22i can be suppressed.

The term intrinsic semiconductor layer here also includes an n⁻ semiconductor layer and a p⁻ semiconductor layer doped with 10¹⁸/cm³ or less.

According to the embodiment as described above, a nonvolatile semiconductor memory device can be realized that enables reduction of the thickness of a rectifying element while maintaining rectifying characteristics of the rectifying element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

For example, the shape, dimensions, material, orientation, and the like of each element provided in the nonvolatile semiconductor memory device are not limited to the examples described above, and may be suitably modified.

Furthermore a p⁺ semiconductor layer 22p or an n⁺ semiconductor layer 22n may be mutually substituted. In this case, when using a p⁺ semiconductor layer 22p, current flow is realized by an increase in the electron concentration, and when using an n⁺ semiconductor layer 22n, current flow is realized by an increase in the positive-hole concentration.

1-19. (canceled)

20. A nonvolatile semiconductor memory device, comprising
a memory portion including a cathode electrode, a memory layer, and a anode electrode;
a rectifying element connected to one of the cathode electrode and the anode electrode,
the rectifying element including a metal layer, a first semiconductor layer, and an insulating layer provided between the metal layer and the first semiconductor layer, and the first semiconductor layer being a p⁺ semiconductor layer or an n⁺ semiconductor layer,
an intrinsic semiconductor layer or one of an n⁻ semiconductor layer and a p⁻ semiconductor layer provided between the first semiconductor layer and the insulating layer; and
a second semiconductor layer provided on a side of the metal layer opposite to the insulating layer, the second semiconductor layer being the p⁺ semiconductor layer or the n⁺ semiconductor layer.

21. The device according to claim 20, wherein an impurity concentration in the first semiconductor layer is not less than 10¹⁸/cm³ and not more than 10²²/cm³.

22. The device according to claim 20, wherein there is a difference between a work function of the metal layer and a Fermi potential of the first semiconductor layer on a side of the metal layer.

23. The device according to claim 20, wherein the insulating layer includes at least one of silicon oxide and silicon oxynitride, and a concentration of oxygen atoms is not less than 1×10¹⁸/cm³.

24. The device according to claim 20, wherein the insulating layer includes at least one of silicon nitride and silicon oxynitride, and a concentration of nitrogen atoms is not less than 1×10¹⁸/cm³.
